(19) United States
(12) Patent Application Publication
(10) Pub. No.: US 2014/0193760 A1
(43) Pub. Date: Jul. 10, 2014

(54) COATED ARTICLE, PROCESS OF COATING AN ARTICLE, AND METHOD OF USING A COATED ARTICLE

(71) Applicant: GENERAL ELECTRIC COMPANY, Schenectady, NY (US)

(72) Inventors: Warren Arthur NELSON, Clifton Park, NY (US); Yuk-Chiu LAU, Ballston Lake, NY (US); Tamara Jean RUSSELL, Ballston Lake, NY (US); Joshua Lee MARGOLIES, Niskayuna, NY (US)

(73) Assignee: GENERAL ELECTRIC COMPANY, Schenectady, NY (US)

(21) Appl. No.: 13/737,104

(22) Filed: Jan. 9, 2013

(51) Int. Cl. C23C 4/04; C23C 14/06

(52) U.S. Cl. CPC C23C 4/04; C23C 14/06
USPC 432/9; 428/212; 428/304.4; 427/446; 427/596

(57) ABSTRACT

A coated article, a process of coating an article, and a process of using an article are disclosed. The coated article includes a substrate, a porous coating material, and a thermal barrier coating material. The porous coating material includes a porosity between about 1 percent and about 20 percent, by volume. The thermal barrier coating material has a thermal conductivity that is lower than a thermal conductivity of the substrate. The porous coating material differs in one or both of composition and microstructure from the thermal barrier coating material. Additionally or alternatively, the porous coating material resists at least one of sintering, densification, and phase destabilization for a predetermined period at a predetermined temperature. The process of coating an article includes applying a coating to form the coated article.

### STATEMENT REGARDING FEDERALLY SPONSORED RESEARCH OR DEVELOPMENT

This invention was made with United States Government support under contract number DE-FC26-05NT42643 awarded by the United States Department of Energy. The United States Government has certain rights in this invention.

### FIELD OF THE INVENTION

The present invention is directed to coated articles, processes of coating articles, and methods of using coated articles. More particularly, the present invention is directed to coatings with porous coating material positioned between a substrate and another material.

### BACKGROUND OF THE INVENTION

Combustion components, such as those in land-based turbines with high firing temperatures, are subjected to high firing temperatures of about 2,600° F., or higher, for an operational cycle of between about 16,000 hours and 24,000 hours. To operate under such conditions, stable thermal barrier coating materials with lower thermal conductivity are desirable.

Standard yttria stabilized zirconia thermal barrier coatings having about 8%, by weight, of Y₂O₃ (8YSZ) with porosity levels of at least 20 percent, by volume, can provide adequate low thermal conductivity. Such coatings can be subjected to a large temperature gradient, for example, between about 1500° F. at a metal substrate and high coating surface temperatures of up to about 2600° F. In addition, such operation cycles can result in microstructural sintering and densification of 8YSZ materials, which can be undesirable. Various degrees of microstructural sintering and densification of the 8YSZ materials can occur through the coating thickness with most densification near the coating surface where the temperatures are high, leading to degradation of coating properties such as increase in thermal conductivity and loss in strain tolerance, which can be undesirable. In addition, the 8YSZ materials suffer phase destabilization from non-transformable tetragonal (t′) phase to the cubic and tetragonal phases at high temperatures above 2200° F. and long operational hours. The tetragonal phase then transforms upon cooling to the monoclinic phase with an associated volume increase which may result in coating spallation near the coating surface.

TBC technology and development has shifted to compositions with increased amounts of rare-earth oxides, such as rare-earth zirconate materials, for lower thermal conductivity and better phase stability that can operate under higher firing temperatures and/or longer operational cycles. However, the disadvantages of such rare-earth zirconate materials can be limited availability and/or high cost.

In addition, coatings including nano-scale features can enhance certain properties. Nano-scale grain size and porosity can provide lower thermal conductivity for conventional thermal barrier coatings. However, in high temperature gas turbines, the thermodynamic driving force results in a growth in size, thereby reducing or eliminating beneficial features.

A coated article, process of coating an article, and method of using a coated article that do not suffer from one or more of the above drawbacks would be desirable in the art.

### BRIEF DESCRIPTION OF THE INVENTION

In an exemplary embodiment, a coated article includes a substrate, a porous coating material positioned proximal to the substrate in comparison to a thermal barrier coating material, and the thermal barrier coating material positioned distal from the substrate in comparison to the porous coating material. The porous coating material includes a porosity between about 1 percent and about 20 percent, by volume. The thermal barrier coating material has a thermal conductivity that is lower than a thermal conductivity of the substrate. The porous coating material differs from the thermal barrier coating material in one or both of composition and microstructure.

In an exemplary embodiment, a coated article includes a substrate, a porous coating material positioned proximal to the substrate in comparison to a thermal barrier coating material, and the thermal barrier coating material positioned distal from the substrate in comparison to the porous coating material. The porous coating material includes a porosity between about 1 percent and about 20 percent, by volume. The thermal barrier coating material has a thermal conductivity that is lower than a thermal conductivity of the substrate. The porous coating material differs in composition from the thermal barrier coating material.

In another exemplary embodiment, a coated article includes a substrate, a porous coating material positioned proximal to the substrate in comparison to a thermal barrier coating material, and the thermal barrier coating material positioned distal from the substrate in comparison to the porous coating material. The porous coating material resists at least one of sintering, densification, and phase destabilization for a period of about 16,000 hours at a temperature of about 2200° F.

Other features and advantages of the present invention will be apparent from the following more detailed description of the preferred embodiment, taken in conjunction with the accompanying drawings which illustrate, by way of example, the principles of the invention.

### BRIEF DESCRIPTION OF THE DRAWINGS

FIG. 1 shows a schematic view of a coated article according to an embodiment of the disclosure.

FIG. 2 shows a schematic view of a coated article according to an embodiment of the disclosure.

FIG. 3 shows thermal conductivity corresponding to an embodiment of the disclosure.

FIG. 4 shows a schematic view of a coated article according to an embodiment of the disclosure.

FIG. 5 shows thermal conductivity corresponding to an embodiment of the disclosure.

Wherever possible, the same reference numbers will be used throughout the drawings to represent the same parts.

### DETAILED DESCRIPTION OF THE INVENTION

Provided is an exemplary coated article, process of coating an article, and method of using a coated article. Embodiments of the present disclosure permit operation at high temperatures or larger temperature gradients, permit formation of a desired thermal conductivity profile, reduce or eliminate undesirable densification of materials, allow higher firing temperatures and/or longer operational cycles, reduce or eliminate reliance upon expensive materials (such as rare-earth materials), decrease manufacturing and/or operational costs, or combinations thereof

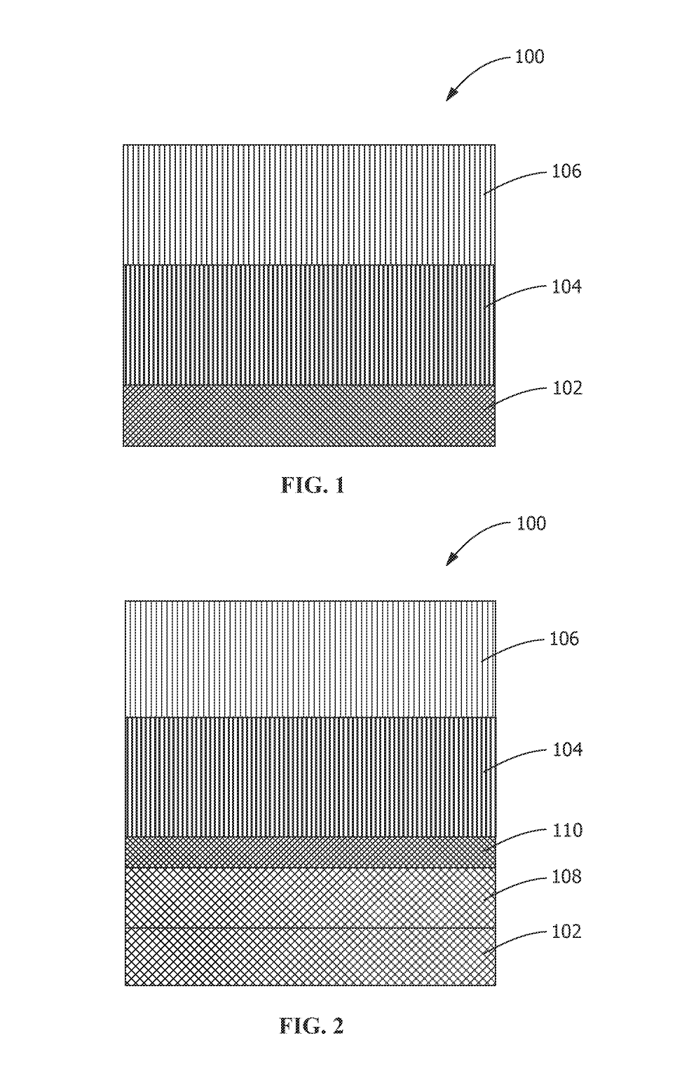

Referring to FIG. 1, in one embodiment, a coated article 100 includes a substrate 102, a porous coating material 104, and a thermal barrier coating material 106. In further embodiments, as is shown in FIG. 2, the coated article 100 further includes a bond coat material 108 and/or a dense vertically cracked thermal barrier coating material 110. In one embodiment, the coated article 100 is a hot gas path component, for example, of a turbine, such as, a land-based turbine or an exhaust region of an aviation engine. In a further embodiment, the coated article 100 is a nozzle, bucket, combustor, or shroud.

The coated article 100 is formed by any suitable process of applying the materials to the substrate 102 in layers or as a graded layer. Suitable processes include, but are not limited to, air plasma spray, high-velocity oxy-fuel spray, suspension thermal spray, chemical vapor deposition, electron beam physical vapor deposition, physical vapor deposition, or a combination thereof. Operational parameters capable of being adjusted or maintained as constant in forming the coated article 100 include, but are not limited to, application distance, application velocity, application temperature, particle size, carrier gas (for example, H₂ or N₂) corresponding to the application of the porous coating material 104, the thermal barrier coating material 106, the bond coat material 108, and/or the dense vertically cracked thermal barrier coating material 110 (see FIG. 2). The materials are applied in a continuous manner or a discontinuous manner; different process methods may be used for the various layers discussed above.

The substrate 102 is any suitable material. Suitable materials include, but are not limited to, nickel-based alloys and cobalt-based alloys. In one embodiment, the substrate 102 has a composition, by weight, of about 22% chromium, about 18% iron, about 9% molybdenum, about 1.5% cobalt, about 0.6% tungsten, about 0.10% carbon, about 1% manganese, about 1% silicon, about 0.008% boron, incidental impurities, and a balance of nickel. In one embodiment, the substrate 102 has a composition, by weight, of between about 50% and about 55% Nickel+Cobalt, between about 17% and about 21% chromium, between about 4.75% and about 5.50% columbium+tantalum, about 0.08% carbon, about 0.35% manganese, about 0.35% silicon, about 0.015% phosphorus, about 0.015% sulfur, about 1.0% cobalt, between about 0.35% and about 0.80% aluminum, between about 2.80% and about 3.30% molybdenum, between about 0.65% and about 1.15% titanium, between about 0.001% and about 0.006% boron, about 0.15% copper, incidental impurities, and a balance of iron.

The porous coating material 104 is positioned proximal to the substrate 102 in comparison to the thermal barrier coating material 106. The porous coating material 104 is formed by any suitable technique, such as, by burning out a fugitive material (for example, polyester) within the porous coating material 104, for example, following plasma spray deposition to form the desired porosity. In one embodiment, the porous coating material 104 is deposited without a fugitive material by selective application, for example, through plasma spray deposition with suitable spray parameters to form desired porosity, such as, but not limited to, gun current, spray distance, and/or feedstock powder size distribution. In one embodiment, the porous coating material 104 is positioned directly on the substrate 102 (see FIG. 1). In another embodiment, the porous coating material 104 is separated from the substrate 102 by one or more additional layers, such as, the bond coat material 108 and/or the dense vertically cracked thermal barrier coating material 110 (see FIG. 2).

The porous coating material 104 includes, by volume, a porosity between about 1 percent and about 20 percent, between about 5 percent and about 10 percent, between about 10 percent and about 20 percent, between about 15 percent and about 20 percent, or any suitable combination, sub-combination, range, or sub-range therein. In further embodiments, the porous coating material 104 includes porosity that increases or decreases between the substrate 102 or other layer proximal to the substrate 102 and the thermal barrier coating material 106, thereby forming a gradient. For example, in one embodiment, the porosity of the porous coating material 104 proximal to the substrate is at about 10 percent and the porosity of the porous coating material 104 proximal to the thermal barrier coating material 106 is at about 20 percent, with the entire porous coating material 104 having a porosity of about 15 percent.

The porous coating material 104 includes a composition and/or microstructure differing from the thermal barrier coating material 106. Suitable compositions of the porous coating material 104 include being substantially devoid of rare-earth metals (for example, rare-earth zirconates), having yttria stabilized zirconia (for example, at a concentration of about 8 percent by weight), having tantalum oxide stabilized material, having MgO, having CaO, having CeO, having lower amounts of rare-earth oxides (for example, by weight, at about 12.5 percent Yb₂O₃ with incidental impurities and a balance ZrO₂), being a ceramic, being a thermal barrier coating-type material, or a combination thereof.

In one embodiment, the thickness of the porous coating material 104 is selected such that the porous coating material 104 is not subjected to a predetermined temperature during a predetermined operational period, for example, capable of otherwise causing phase destabilization and/or severe sintering/densification. In one embodiment with 8YSZ as the porous coating material 104, the predetermined temperature is about 2200° F. and the predetermined operational period is 16,000 hours.

In one embodiment, the porous coating material 104 includes nano-structures. Being positioned within the porous coating material 104, the nano-structures are able to resist the thermodynamic driving force during operation, such as, in a gas turbine. The nano-structures are any suitable material, for example, materials including rare-earth zirconates or non-rare-earth zirconates.

FIG. 3 shows the thermal conductivities of the porous coating material 104 and the thermal barrier coating material 106. The porous coating material 104 is an 8YSZ coating with porosity of less than about 20 percent, by volume, and the thermal barrier coating material 106 is a dense rare-earth zirconate, such as, YbZirc coating having a predetermined composition (for example, by weight, about 68.9 percent Yb₂O₃ with incidental impurities and a balance ZrO₂) and/or a predetermined porosity (for example, less than about 5 percent, by volume). The thermal conductivity of the 8YSZ coating is lower than that of the YbZirc coating at a temperature below about 2200° F., but gradually increases with temperature due to sintering and/or densification until above about 2200° F., when the thermal conductivity of the 8YSZ coating is higher than that of the YbZirc coating. Additionally or alternatively, the thermal barrier coating material 106 includes a porosity, by volume, of less than about 5 percent, of less than about 3 percent, of less than about 1 percent, of about 5 percent, of between about 1 percent and about 5 percent, of between about 3 percent and about 5 percent, or any suitable combination, sub-combination, range, or sub-range therein.

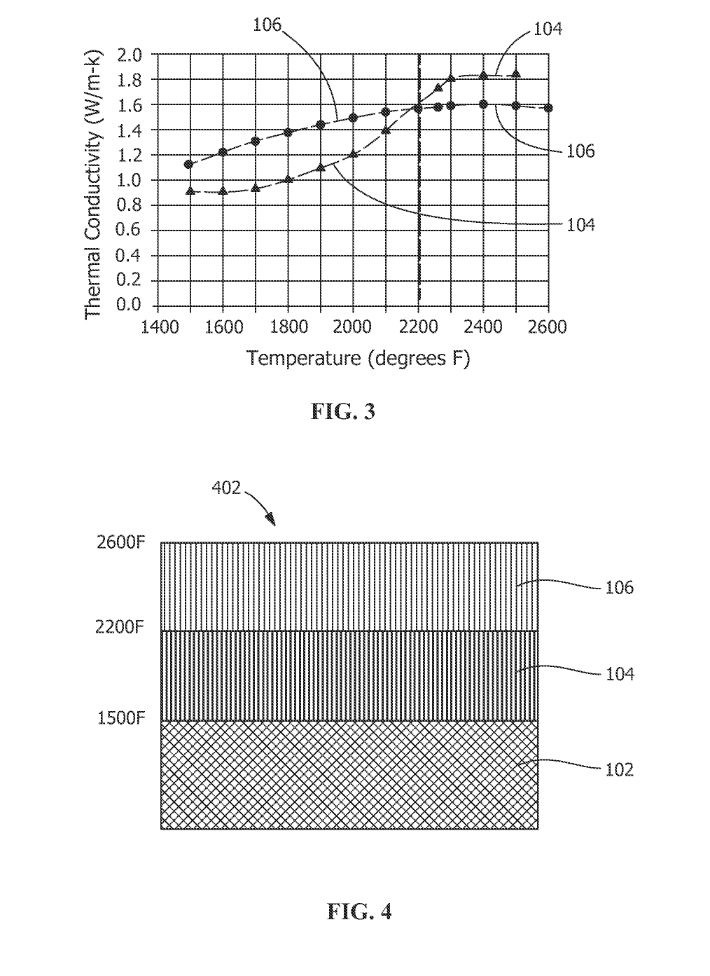

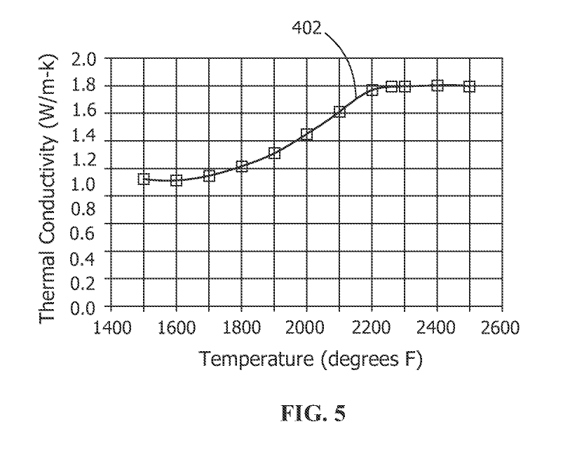

In one embodiment, as is shown in FIG. 4, the porous coating material 104 and the thermal barrier coating material 106 operate as a coating system 402 combining the lowest thermal conductivity values of the individual coatings as is shown in FIG. 5. In this embodiment, the coating system is stable over a predetermined temperature range, for example, between about 1,500° F. and about 2,600° F., with the porous coating material 104 being stable below a first temperature (for example, 2,200° F.) (by selecting an appropriate thickness of the porous coating material 104 based upon heat-transfer considerations and/or system/turbine design parameters) and the thermal barrier coating material 106 being stable below a second temperature (for example, 2,600° F.), which is higher than the first temperature. In one embodiment, the thermal barrier coating material 106 is 20YSZ (20% by weight, Y₂O₃ with incidental impurities and a balance ZrO₂) which is fully stabilized in the cubic phase and is stable to 2,600° F.

Referring to FIG. 2, in one embodiment, the coated article 100 includes the bond coat material 108 positioned between the porous coating material 104 and the substrate 102. The bond coat material 108 abuts the substrate 102, the porous coating material 104, other materials or layers (not shown), or any suitable combination thereof. The bond coat material 108 is any suitable material providing adhesion between the substrate 102 and/or the porous coating material 104. For example, in one embodiment, the bond coat material 108 is or includes MCrAlY. In one embodiment, the bond coat material 108 includes a thickness, for example, between about 2 mils and about 10 mils, between about 2 mils and about 5 mils, between about 5 mils and about 10 mils, between about 1 mil and about 2 mils, or any suitable combination, sub-combination, range, or sub-range therein.

Also as shown in FIG. 2, in one embodiment, the coated article 100 includes the dense vertically cracked thermal barrier coating material 110 abutting the porous coating material 104 and/or abutting or forming a portion of the thermal barrier coating material 106. The dense vertically cracked thermal barrier coating material 110 is any suitable material providing adhesion between the substrate 102, the porous coating material 104, and/or the bond coat material 108, to improve coating life against spallation. For example, in one embodiment, the dense vertically cracked thermal barrier coating material 110 is or includes being substantially devoid of rare-earth metals (for example, rare-earth zirconates), having yttria stabilized zirconia (for example, at a concentration of about 8 percent by weight), having MgO, having CaO, having CeO, being a ceramic, being a thermal barrier coating-type material, or a combination thereof. In one embodiment, the dense vertically cracked thermal barrier coating material 110 includes a thickness, for example, between about 2 mils and about 10 mils, between about 2 mils and about 5 mils, between about 5 mils and about 10 mils, between about 1 mil and about 2 mils, or any suitable combination, sub-combination, range, or sub-range therein.

While the invention has been described with reference to a preferred embodiment, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A coated article, comprising:
a substrate;
a porous coating material positioned proximal to the substrate in comparison to a thermal barrier coating material; and
the thermal barrier coating material positioned distal from the substrate in comparison to the porous coating material;
wherein the porous coating material includes a porosity between about 1 percent and about 20 percent, by volume;
wherein the thermal barrier coating material has a thermal conductivity that is lower than a thermal conductivity of the substrate;
wherein the porous coating material differs from the thermal barrier coating material in one or both of composition and microstructure.

2. The coated article of claim 1, wherein the thermal barrier coating material includes a rare-earth zirconate.

3. The coated article of claim 1, wherein the porous coating material is substantially devoid of rare-earth metals.

4. The coated article of claim 1, wherein the porous coating material is substantially devoid of rare-earth zirconates.

5. The coated article of claim 1, wherein the porous coating material resists at least one of sintering, densification, and phase destabilization for a predetermined exposure period at a predetermined temperature.

6. The coated article of claim 1, wherein the porous coating material includes yttria stabilized zirconia.

7. The coated article of claim 1, wherein the porous coating material includes tantalum oxide stabilized material, MgO, CaO, CeO, or a combination thereof

8. The coated article of claim 1, wherein the porous coating material includes nano-structures.

9. The coated article of claim 1, wherein the thermal barrier coating material includes, by weight, about 68.9 percent Yb₂O₃, incidental impurities, and a balance ZrO₂.

10. The coated article of claim 1, wherein the thermal barrier coating includes a porosity of less than about 5 percent.

11. The coated article of claim 1, further comprising a bond coat material positioned between the porous coating material and the substrate.

12. The coated article of claim 11, wherein the bond coat material includes MCrAlY.

13. The coated article of claim 11, further comprising a dense vertically cracked thermal barrier coating material.

14. The coated article of claim 13, wherein the dense vertically cracked thermal barrier coating material includes yttria stabilized zirconia.

15. The coated article of claim 1, wherein one or both of the thermal barrier coating material and the porous coating material are applied by air plasma spray, high-velocity oxy-fuel spray, electron beam physical vapor deposition, or a combination thereof.

16. The coated article of claim 1, wherein the thermal barrier coating material includes by weight, about 20 percent Y₂O₃, incidental impurities, and a balance ZrO₂.

17. A process of applying the coating of claim 1.

18. A process of using the coating of claim 1, wherein the porous coating material is at least partially subjected to a temperature of about 2200° F. for a period of about 16,000 hours, wherein the porous coating material resists at least one of sintering, densification, and phase destabilization.

19. A coated article, comprising:
a substrate;
a porous coating material positioned proximal to the substrate in comparison to a thermal barrier coating material; and
the thermal barrier coating material positioned distal from the substrate in comparison to the porous coating material;
wherein the porous coating material includes a porosity between about 1 percent and about 20 percent, by volume;
wherein the thermal barrier coating material has a thermal conductivity that is lower than a thermal conductivity of the substrate;
wherein the porous coating material differs in composition from the thermal barrier coating material.

20. A coated article, comprising:
a substrate;
a porous coating material positioned proximal to the substrate in comparison to a thermal barrier coating material; and
the thermal barrier coating material positioned distal from the substrate in comparison to the porous coating material;
wherein the porous coating material resists at least one of sintering, densification, and phase destabilization for a period of about 16,000 hours at a temperature of about 2200° F.
